(19) United States
(12) Patent Application Publication
(10) Pub. No.: US 2026/0194929 A1
(43) Pub. Date: Jul. 9, 2026

(54) DISTRIBUTED VOLTAGE REGULATING CIRCUIT, METHOD OF OPERATING DISTRIBUTED VOLTAGE REGULATING CIRCUIT, AND SYSTEM-ON-CHIP INCLUDING DISTRIBUTED VOLTAGE REGULATING CIRCUIT

(71) Applicant: Samsung Electronics Co., Ltd., Suwon-si (KR)

(72) Inventors: Jaeseung Lee, Suwon-si (KR); Sungwan Hong, Seoul (KR); Junhyeok Yang, Suwon-si (KR); Sungmin Yoo, Suwon-si (KR); Jeonghun Kim, Seoul (KR)

(73) Assignees: Samsung Electronics Co., Ltd., Suwon-si (KR); Sogang University Research & Business Development Foundation, Seoul (KR)

(21) Appl. No.: 19/444,005

(22) Filed: Jan. 8, 2026

(30) Foreign Application Priority Data
Jan. 9, 2025 (KR) 10-2025-0003746
Apr. 29, 2025 (KR) 10-2025-0056751

(51) Int. Cl. G05F 1/56; G01R 19/25; G05F 1/62; G06F 1/30

(52) U.S. Cl. CPC G05F 1/561; G01R 19/2509; G05F 1/62; G06F 1/30

(57) ABSTRACT

A distributed voltage regulating circuit includes a main voltage regulator including a first power transistor configured to provide a first current to an output node, an auxiliary voltage regulator including a second power transistor configured to provide a second current to the output node, and a first control line and a second control line connecting the main voltage regulator to the auxiliary voltage regulator, wherein the main voltage regulator is configured to generate a first control signal and a second control signal, provide the first control signal to the auxiliary voltage regulator through the first control line, and provide the second control signal to the auxiliary voltage regulator through the second control line, and the auxiliary voltage regulator is configured to generate a first differential amplification signal for the first control signal and the second control signal and control the second power transistor based on the first differential amplification signal.

### CROSS-REFERENCE TO RELATED APPLICATIONS

This present application claims priority to and the benefit under 35 U.S.C. § 119(a)-(d) of Korean Patent Application No. 10-2025-0003746, filed on Jan. 9, 2025, and Korean Patent Application No. 10-2025-0056751, filed on Apr. 29, 2025, in the Korean Intellectual Property Office, the entire disclosure of which are incorporated herein by reference.

### FIELD

The disclosed concepts relate to a distributed voltage regulating circuit, to a method of operating a distributed voltage regulating circuit and to a system-on-chip, and more particularly, to a system-on-chip including a distributed voltage regulating circuit.

### BACKGROUND

LowDropOut regulators (LDOs) may be placed in system-on-chips to provide power to various functional blocks.

As the integration of system-on-chips increases and low-power functions are required, a distributed LDO technology for placing a plurality of LDOs in system-on-chips has been applied to provide power stability.

When a current imbalance occurs between distributed LDOs, only some LDOs may generate excessive current in order to supply constant power, which may cause a heat imbalance in system-on-chips.

### SUMMARY

The disclosed concepts provide a distributed voltage regulating circuit that performs current balancing between a plurality of power regulators.

The disclosed concepts provide a distributed voltage regulating circuit that quickly recovers a voltage drop when the voltage drop occurs.

According to aspects of the disclosed concepts, there is provided a distributed voltage regulating circuit including a main voltage regulator including a first power transistor configured to provide a first current to an output node, an auxiliary voltage regulator including a second power transistor configured to provide a second current to the output node, and a first control line and a second control line connecting the main voltage regulator to the auxiliary voltage regulator, wherein the main voltage regulator is configured to generate a first control signal and a second control signal, provide the first control signal to the auxiliary voltage regulator through the first control line, and provide the second control signal to the auxiliary voltage regulator through the second control line, and the auxiliary voltage regulator is configured to generate a first differential amplification signal for the first control signal and the second control signal and control the second power transistor based on the first differential amplification signal.

According to aspects of the disclosed concepts, there is provided an operating method of a distributed voltage regulating circuit including a main voltage regulator and an auxiliary voltage regulator, the operating method including comparing, by the main voltage regulator, a feedback voltage of an output node with a reference voltage to generate an error voltage, controlling, by the main voltage regulator, a first power transistor based on the error voltage to provide a first current to the output node, generating, by the main voltage regulator, a first control signal based on the error voltage, generating, by the main voltage regulator, a second control signal based on a current difference between a first sampling current of the first power transistor and a second sampling current of a second power transistor in the auxiliary voltage regulator, providing, by the main voltage regulator, the first control signal and the second control signal to the auxiliary voltage regulator, and controlling, by the auxiliary voltage regulator, the second power transistor based on a differential amplification signal for the first control signal and the second control signal to provide a second current to the output node.

According to aspects of the disclosed concepts, there is provided a system-on-chip including a main voltage regulator including a first power transistor configured to provide a first current to an output node based on a feedback voltage and a reference voltage, an auxiliary voltage regulator including a second power transistor configured to provide a second current to the output node based on a first control signal and a second control signal, and at least one load circuit configured to operate based on a voltage of the output node, wherein the main voltage regulator is configured to generate the first control signal based on the feedback voltage and the reference voltage and generate the second control signal based on a first sampling current of the first power transistor and a second sampling current of the second power transistor.

### BRIEF DESCRIPTION OF THE DRAWINGS

Embodiments will be more clearly understood from the following detailed description taken in conjunction with the accompanying drawings in which:

FIG. 1 is a block diagram of an electronic device according to embodiments;

FIG. 2 is a diagram illustrating a distributed voltage regulating circuit according to embodiments;

FIG. 3 is a diagram illustrating the arrangement of control lines according to embodiments;

FIG. 4 is a diagram illustrating a distributed voltage regulating circuit according to embodiments;

FIG. 5 is a diagram illustrating a distributed voltage regulating circuit according to embodiments;

FIG. 6 is a diagram illustrating a distributed voltage regulating circuit according to embodiments;

FIG. 7 is a diagram illustrating a capacitor amplification circuit according to embodiments;

FIG. 8 is a diagram illustrating a capacitor amplification method according to embodiments;

FIG. 9 is a flowchart illustrating an operating method of a distributed voltage regulating circuit according to embodiments; and

FIG. 10 is a circuit diagram of a distributed voltage regulating circuit according to embodiments.

### DETAILED DESCRIPTION

Hereinafter, embodiments of the disclosed concepts will be described in detail with reference to the attached drawings.

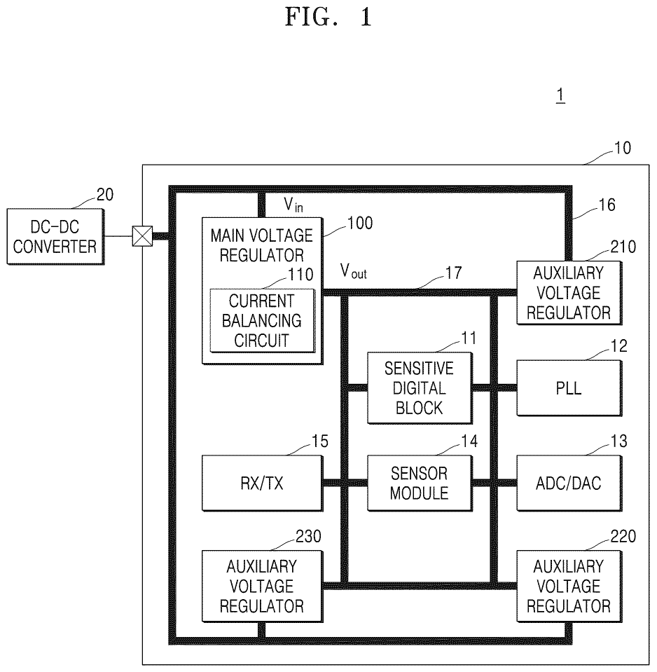

FIG. 1 is a block diagram of an electronic device 1 according to embodiments.

Referring to FIG. 1, the electronic device 1 may include a system-on-chip 10 and a direct current (DC)-DC converter 20.

The DC-DC converter 20 may generate an input voltage Vᵢₙ by stepping down or stepping up an external power supply voltage. The input voltage Vᵢₙ generated by the DC-DC converter 20 may be provided to the system-on-chip 10.

The system-on-chip 10 may include a main voltage regulator 100, auxiliary voltage regulators 210, 220, and 230, and power rails 16 and 17. In addition, the system-on-chip 10 may include various functional blocks. For example, the system-on-chip 10 may include a sensitive digital block 11, a phase-locked loop (PLL) 12, an analog-to-digital converter (ADC)/digital-to-analog converter (DAC) 13, a sensor module 14, and a transmitter/receiver 15. The sensitive digital block 11 may include a logic circuit that is sensitive to voltage fluctuations or voltage noise, and may require a low-noise power supply voltage. The PLL 12 may amplify a reference clock signal to generate a system clock signal that is provided to each functional block. The ADC/DAC 13 may convert an analog signal into a digital signal and provide the digital signal to each functional block, or may convert a digital signal received from each functional block into an analog signal. The sensor module 14 may measure environmental data, such as temperature, current, voltage, and pressure. The transmitter/receiver 15 may receive data from outside the system-on-chip 10 or transmit data to the outside of the system-on-chip 10. The transmitter/receiver 15 may include a data serializer circuit and a deserializer circuit. Each functional block may require a low-noise power supply voltage to provide improved performance. The functional blocks included in the system-on-chip 10 are not limited thereto. Each of the functional blocks may be implemented by a set of circuits or modules designed to perform a unique function, and may also be referred to as an intellectual property (IP) block. In the present specification, in terms of using an output voltage Vₒᵤₜ provided by the main voltage regulator 100 and the auxiliary voltage regulators 210, 220, and 230, the functional block may also be referred to as a load circuit.

The system-on-chip 10 may receive the input voltage Vᵢₙ from the DC-DC converter 20. The input voltage Vᵢₙ may be provided to the main voltage regulator 100 and the auxiliary voltage regulators 210, 220, and 230 through the power rail 16. The power rail 16 may have a ring structure arranged along the edge of the system-on-chip 10. However, embodiments are not limited thereto.

The main voltage regulator 100 and the auxiliary voltage regulators 210, 220, and 230 may regulate the input voltage Vᵢₙ to generate the output voltage Vₒᵤₜ and may provide the output voltage Vₒᵤₜ to the power rail 17. The output voltage Vₒᵤₜ may be provided to each functional block through the power rail 17. Although the system-on-chip 10 is illustrated as including three auxiliary voltage regulators, embodiments are not limited thereto.

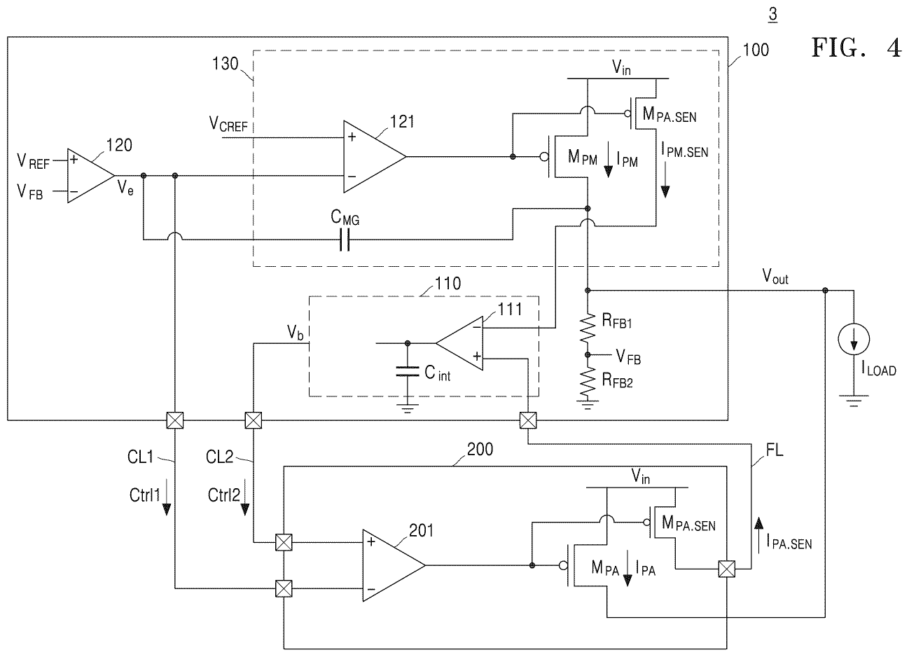

The main voltage regulator 100 and the auxiliary voltage regulators 210, 220, and 230 may be distributedly arranged at the edge of the system-on-chip 10. However, embodiments are not limited thereto. The main voltage regulator 100 and the auxiliary voltage regulators 210, 220, and 230 may include power transistors (e.g., M_{PM} and M_{PA} of FIGS. 4 to 6, and 10) and may maintain the voltage of the power rail 17 at the output voltage Vₒᵤₜ by providing current to the power rail 17 through the power transistors. That is, the main voltage regulator 100 and the auxiliary voltage regulators 210, 220, and 230 may provide a stable voltage to the functional blocks by providing current to the power rail 17. When the power consumption of a certain functional block increases, a voltage regulator closest to the functional block may apply a relatively larger current to the power rail 17 in order to maintain the output voltage Vₒᵤₜ constant, and thus, a current imbalance may occur between the voltage regulators. Due to the current imbalance, excessive heat may concentrate in a certain voltage regulator, and the temperature of the system-on-chip 10 may locally increase.

According to embodiments, the main voltage regulator 100 may include a current balancing circuit 110. The current balancing circuit 110 may monitor the current of a power transistor included in the main voltage regulator 100 and the current of a power transistor included in each of the auxiliary voltage regulators 210, 220, and 230, and may control the power transistors based on a current difference, thereby achieving uniform power distribution and heat dissipation.

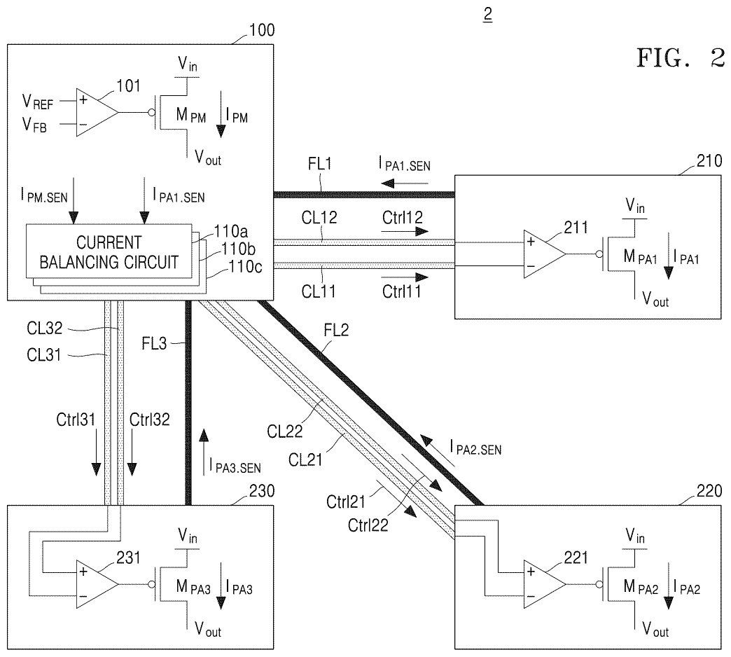

FIG. 2 is a diagram illustrating a distributed voltage regulating circuit 2 according to embodiments.

Referring to FIG. 2, the distributed voltage regulating circuit 2 may include a main voltage regulator 100 and auxiliary voltage regulators 210, 220, and 230. Hereinafter, the description of the auxiliary voltage regulator 210 may also apply to the auxiliary voltage regulators 220 and 230.

Each of the auxiliary voltage regulators 210, 220, and 230 may be connected to the main voltage regulator 100 via two control lines and one feedback line. For example, the main voltage regulator 100 may be connected to the auxiliary voltage regulator 210 via control lines CL11 and CL12 and a feedback line FL1.

The main voltage regulator 100 may provide control signals to each auxiliary voltage regulator via two control lines and receive sampling current from each auxiliary voltage regulator via one feedback line. For example, the main voltage regulator 100 may provide control signals Ctrl11 and Ctrl12 via the control lines CL11 and CL12 and receive a sampling current I_{PA1.SEN} via the feedback line FL1.

The auxiliary voltage regulator 210 may include an amplifier 211 and a power transistor M_{PA1}. The amplifier 211 may generate a differential amplification signal for the control signals Ctrl11 and Ctrl12, and the power transistor M_{PA1} may generate a current I_{PA1} based on the differential amplification signal. The current I_{PA1} may be provided to the power rail 17 to maintain the voltage of the power rail 17 at the output voltage Vₒᵤₜ. Although not shown in the drawings, various circuits may be arranged between the amplifier 211 and the power transistor M_{PA1}. The auxiliary voltage regulator 210 may generate a sampling current I_{PA1.SEN} for the current I_{PA1} and provide the sampling current I_{PA1.SEN} to the main voltage regulator 100 via the feedback line FL1. The current level of the sampling current I_{PA1.SEN} may be 1/N times the current level of the current I_{PA1}. That is, the sampling current I_{PA1.SEN} may refer to a current sampled N:1 for the current I_{PA1}.

The main voltage regulator 100 may include an amplifier 101 and a power transistor M_{PM}.

The amplifier 101 may generate a differential amplification signal for a reference voltage V_{REF} and a feedback voltage V_{FB}, and the power transistor M_{PM} may generate a current I_{PM} based on the differential amplification signal. The level of the output voltage Vₒᵤₜ may be stabilized based on iterative feedback loop until the feedback voltage V_{FB} converges to the reference voltage V_{REF}. That is, as the level of the current I_{PM} is adjusted based on the error between the feedback voltage V_{FB} and the reference voltage V_{REF}, the voltage of the power rail 17 may be maintained at the output voltage Vₒᵤₜ. The feedback voltage V_{FB} may have the same voltage level as the output voltage Vₒᵤₜ or may have a sampled voltage level. Although not shown in the drawings, various circuits may be arranged between the amplifier 101 and the power transistor M_{PM}.

The main voltage regulator 100 may generate a sampling current I_{PM.SEN} for the current I_{PM}. The current level of the sampling current I_{PM.SEN} may be 1/N times the current level of the current I_{PM}. In other words, the sampling current I_{PM.SEN} may refer to a current sampled N:1 for the current I_{PM}.

The main voltage regulator 100 may include a plurality of current balancing circuits 110a, 110b, and 110c. The plurality of current balancing circuits 110a, 110b, and 110c may correspond to the plurality of auxiliary voltage regulators 210, 220, and 230, respectively. Each of the current balancing circuits 110a, 110b, and 110c may receive a sampling current from a corresponding auxiliary voltage regulator and provide control signals to the corresponding auxiliary voltage regulator. For example, the current balancing circuit 110a may receive a sampling current I_{PA1.SEN} from the auxiliary voltage regulator 210 and provide the control signals Ctrl11 and Ctrl12 to the auxiliary voltage regulator 210. The description of the current balancing circuit 110a may apply to the current balancing circuits 110b and 110c.

The main voltage regulator 100 may generate the control signal Ctrl1 based on the differential amplification signal output by the amplifier 101. The current balancing circuit 110a may generate the control signal Ctrl2 based on a difference between the sampling current I_{PM.SEN} and the sampling current I_{PA1.SEN}.

The auxiliary voltage regulator 210 may adjust the level of the current I_{PA1} by using the control signal Ctrl11 generated based on the differential amplification signal for the reference voltage V_{REF} and the feedback voltage V_{FB}, and thus, the level of the output voltage Vₒᵤₜ may be stabilized. In addition, the auxiliary voltage regulator 210 may adjust the level of the current I_{PA1} by using the control signal Ctrl12 generated based on the difference between the sampling current I_{PM.SEN} and the sampling current I_{PA1.SEN}, and thus, level balancing between the current I_{PA1} and the current I_{PM} may be performed.

However, because the control signals Ctrl11 and Ctrl12 are provided through different control lines CL11 and CL12, noise due to a transfer path may be amplified by the amplifier 211.

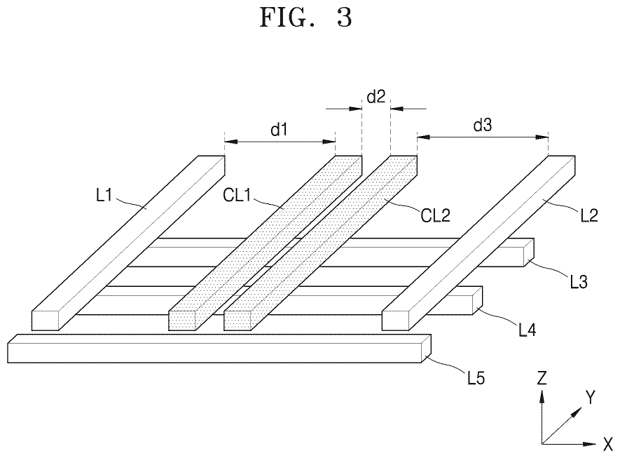

FIG. 3 is a diagram illustrating the arrangement of control lines CL1 and CL2 according to embodiments.

Referring to FIG. 3, the control line pair CL1 and CL2 may correspond to each of the control line pairs CL11 and CL12, CL21 and CL22, and CL31 and CL 32 of FIG. 2.

The control lines CL1 and CL2 may be adjacent to each other in a first horizontal direction (the X direction) and may extend in a second horizontal direction (the Y direction). The control lines CL1 and CL2 may be formed in the same metal layer. For example, the control lines CL1 and CL2 may be formed in a first metal layer, and lines extending in the second horizontal direction may be formed in the first metal layer. Lines L1 and L2 may be further formed in the first metal layer. For example, the lines L1 and L2 may be signal lines providing various signals to the functional block.

Lines extending in the first horizontal direction may be formed in a second metal layer located below the first metal layer in a vertical direction (the Z direction). For example, lines L3, L4, and L5 may be formed in the second metal layer.

The control lines CL1 and CL2 may be apart from each other by d2 in the first horizontal direction. The control line CL1 may be apart from the line L1 by d1, and the control line CL2 may be apart from the line L2 by d3. d2 may be less than or equal to a preset first distance. d1 and d3 may exceed a preset second distance. The second distance may be equal to or greater than the first distance.

Although not shown in the drawings, the control lines CL1 and CL2 may be connected to lines spaced apart by d2 in the second horizontal direction in the second metal layer and form a transfer path.

Because the control lines CL1 and CL2 are arranged adjacent to each other at a relatively close distance, common noise may be induced in the control signals Ctrl1 and Ctrl2 transferred through the control lines CL1 and CL2. The amplifier 211 included in the auxiliary voltage regulator 210 may generate a differential amplification signal for the control signals Ctrl1 and Ctrl2 to remove the noise induced in the control signals Ctrl1 and Ctrl2. Accordingly, an electronic device including the control lines CL1 and CL2 may provide power stability that is robust to noise occurring in a signal transfer path.

FIG. 4 is a diagram illustrating a distributed voltage regulating circuit 3 according to embodiments.

Referring to FIG. 4, the distributed voltage regulating circuit 3 may include a main voltage regulator 100 and an auxiliary voltage regulator 200. The auxiliary voltage regulator 200 may correspond to the auxiliary voltage regulators 210, 220, and 230 of FIGS. 1 and 2.

The main voltage regulator 100 may include a current balancing circuit 110, an amplifier 120, and a core voltage regulator 130.

The amplifier 120 may amplify a difference between a reference voltage V_{REF} and a feedback voltage V_{FB} to generate an error voltage Vₑ. The error voltage Vₑ may be a differential amplification signal. The feedback voltage V_{FB} may be sampled based on an output voltage Vₒᵤₜ. Specifically, the feedback voltage V_{FB} may have a voltage level divided by resistors R_{FB1} and R_{FB2} connected to an output node to which the output voltage Vₒᵤₜ is provided. The error voltage Vₑ may be provided to the core voltage regulator 130.

The core voltage regulator 130 may include an amplifier 121, a power transistor M_{PM}, a sensing transistor M_{PM.SEN}, and a capacitor C_{MG}.

The amplifier 121 may amplify a difference between the error voltage Vₑ and a core reference voltage V_{CREF} and output the amplified difference. The output of the amplifier 121 may be provided to a gate of the power transistor M_{PM}, and a current I_{PM} may be provided to the output node through a drain terminal of the power transistor M_{PM}. In addition, the output of the amplifier 121 may be provided to a gate of the sensing transistor M_{PM.SEN}, and a current I_{PM.SEN} may be provided to the current balancing circuit 110 through a drain terminal of the sensing transistor M_{PM.SEN}.

A source of the power transistor M_{PM} and a source of the sensing transistor M_{PM.SEN} may be connected to an input voltage (Vᵢₙ) node. The ratio of the size of the power transistor M_{PM} to the size of the sensing transistor M_{PM.SEN} may be N:1. Therefore, the ratio of the current I_{PM} to the current I_{PM.SEN} may be N:1. The gate of the power transistor M_{PM} and the gate of the sensing transistor M_{PM.SEN} may be connected to each other.

The capacitor C_{MG} may be connected between an output terminal of the amplifier 120 and the output node to which the output voltage Vₒᵤₜ is provided. When a functional block temporarily consumes a lot of power and a load current ILOAD increases, the output voltage Vₒᵤₜ may temporarily drop sharply. The capacitor C_{MG} may prevent a sharp drop of the output voltage Vₒᵤₜ and may improve the stability of a feedback loop by compensating for a dominant pole formed by the amplifier 120.

The auxiliary voltage regulator 200 may include an amplifier 201, a power transistor M_{PA}, and a sensing transistor M_{PA.SEN}. The structure of the auxiliary voltage regulator 200 may be the same as the structure of the core voltage regulator 130.

The amplifier 201 may receive control signals Ctrl1 and Ctrl2 through control lines CL1 and CL2 and amplify a difference between the control signal Ctrl1 and the control signal Ctrl2. The control signal Ctrl1 may be an error voltage Vₑ of the amplifier 120, and the control signal Ctrl2 may be an output voltage V_{b} of the current balancing circuit 110.

When a functional block temporarily consumes a lot of power and the load current ILOAD increases, the output voltage Vₒᵤₜ may temporarily drop sharply and the feedback voltage V_{FB} may decrease. Accordingly, the error voltage Vₑ may increase, and the output voltages of the amplifier 121 and the amplifier 201 may be adjusted. Because the adjusted output voltages of the amplifiers 121, 201 control the power transistors M_{PM} and M_{PA} to increase the currents I_{PM} and I_{PA}, the output voltage Vₒᵤₜ may be quickly stabilized.

The output of the amplifier 201 may be provided to a gate of the power transistor M_{PA}, and a current I_{PA} may be provided to the output node through a drain terminal of the power transistor M_{PA}. In addition, the output of the amplifier 201 may be provided to a gate of the sensing transistor M_{PA.SEN}, and a current I_{PA.SEN} may be provided to the main voltage regulator 100 through a drain terminal of the sensing transistor M_{PA.SEN}. The current I_{PA.SEN} may be provided to the main voltage regulator 100 through a feedback line FL.

A source of the power transistor M_{PA} and a source of the sensing transistor M_{PA.SEN} may be connected to an input voltage (Vᵢₙ) node. The ratio of the size of the power transistor M_{PA} to the size of the sensing transistor M_{PA.SEN} may be N:1. Therefore, the ratio of the current I_{PA} to the current I_{PA.SEN} may be N:1. The gate of the power transistor M_{PA} and the gate of the sensing transistor M_{PA.SEN} may be connected to each other.

The current balancing circuit 110 may include an amplifier 111 and an integration capacitor Cᵢₙₜ.

The amplifier 111 may receive the current I_{PM.SEN} and the current I_{PA.SEN} and amplify a difference between the current I_{PM.SEN} and the current I_{PA.SEN}.

The integration capacitor Cᵢₙₜ may be charged based on the output voltage of the amplifier 111. The current balancing circuit 110 may generate a bias voltage V_{b} based on a charge voltage of the integration capacitor Cᵢₙₜ. For example, when the difference between the current I_{PA.SEN} and the current I_{PM.SEN} is not 0, the current balancing circuit 110 may adjust the bias voltage V_{b} and provide the bias voltage V_{b} as the control signal Ctrl2 to the auxiliary voltage regulator 200. When the bias voltage V_{b} is adjusted, the output voltage of the amplifier 201 included in the auxiliary voltage regulator 200 is adjusted and the current I_{PA.SEN} of the sensing transistor M_{PA.SEN} is adjusted according to the adjusted output voltage of the amplifier 201, and thus, the current level of the current I_{PA.SEN} may converge to the current level of the current I_{PM.SEN}.

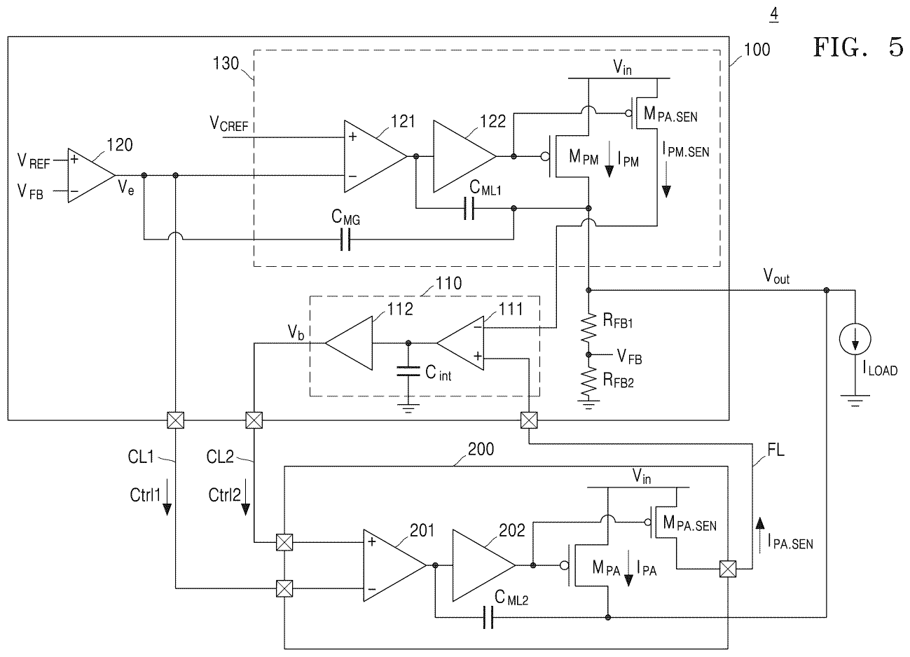

FIG. 5 is a diagram illustrating a distributed voltage regulating circuit 4 according to embodiments. Hereinafter, the descriptions given above with reference to FIG. 4 may be omitted.

Compared with the distributed voltage regulating circuit 3 of FIG. 4, the distributed voltage regulating circuit 4 may further include buffers 122 and 202, an inverting circuit 112, and capacitors C_{ML1} and C_{ML2}.

The buffer 122 may receive the output voltage of the amplifier 121 as an input and output a voltage having the same logic level as the input output voltage. For example, the buffer 122 may include a pull-up stage providing a large current and a pull-down stage discharging a large current, thereby generating a voltage providing a faster response than the output voltage of the amplifier 121. That is, the power transistor M_{PM} may be quickly driven through the buffer 122.

Similarly, the buffer 202 may receive the output voltage of the amplifier 201 as an input and output a voltage having the same logic level as the input output voltage. For example, the buffer 202 may include a pull-up stage providing a large current and a pull-down stage discharging a large current, thereby generating a voltage providing a faster response than the output voltage of the amplifier 201. That is, the power transistor M_{PA} may be quickly driven through the buffer 202.

The inverting circuit 112 may generate a bias voltage V_{b} that decreases as a charge voltage of the capacitor Ciₙₜ increases. That is, the bias voltage V_{b} of a level inversely proportional to the difference between the current I_{PA.SEN} and the current I_{PM.SEN} may be generated and input to the + terminal of the amplifier 201, and thus, level balancing between the current I_{PA.SEN} and the current I_{PM.SEN} may be performed.

The capacitor C_{ML1} may be connected between an output terminal of the amplifier 121 and an output voltage (Vₒᵤₜ) node. A capacitor C_{ML1} may be connected between an input terminal of the buffer 122 and the output voltage (Vₒᵤₜ) node. The capacitor C_{ML1} may prevent a sudden drop in the output voltage Vₒᵤₜ caused by a functional block located near the main voltage regulator 100.

The capacitor C_{ML2} may be connected between an output terminal of the amplifier 201 and the output voltage (Vₒᵤₜ) node. The capacitor C_{ML2} may be connected between an input terminal of the buffer 202 and the output voltage (Vₒᵤₜ) node. The capacitor C_{ML2} may prevent a sudden drop in the output voltage Vₒᵤₜ by a functional block located near the main voltage regulator 100.

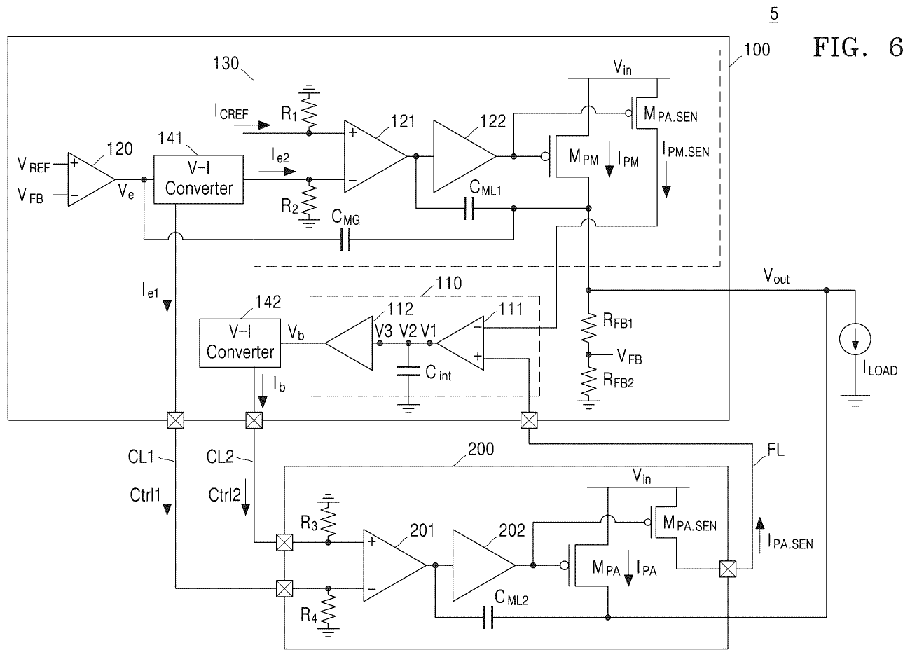

FIG. 6 is a diagram illustrating a distributed voltage regulating circuit 5 according to embodiments. Hereinafter, the descriptions given above with reference to FIGS. 4 and 5 may be omitted.

Compared to the distributed voltage regulating circuit 4 of FIG. 5, the distributed voltage regulating circuit 5 may further include voltage-current conversion circuits (V-I converters) 141 and 142 and resistors R₁, R₂, R₃, and R₄.

The voltage-current conversion circuit 141 may convert the error voltage Vₑ of the amplifier 120 into a current Iₑ₁ and a current Iₑ₂. For example, the voltage-current conversion circuit 141 may include a first transistor that receives the error voltage Vₑ at a gate terminal thereof and outputs the current Iₑ₁, and a second transistor that receives the output voltage Vₑ at a gate terminal thereof and outputs the current Iₑ₂. However, embodiments are not limited thereto, and the voltage-current conversion circuit 141 may be one of various circuits that convert voltage into current.

The amplifier 121 may receive, through the + terminal thereof, a voltage caused by a core reference current I_{CREF} and the resistor R₁, and may receive, through the − terminal thereof, a voltage caused by the current Iₑ₂ and the resistor R₂.

The voltage-current conversion circuit 142 may convert the output voltage V_{b} of the current balancing circuit 110 into a current I_{b}. The current I_{b} may also be referred to as a bias current. For example, the voltage-current conversion circuit 142 may be a voltage-controlled current source or a transconductance amplifier controlled by the output voltage V_{b}. However, embodiments are not limited thereto, and the voltage-current conversion circuit 141 may be one of various circuits that convert voltage into current.

The amplifier 201 may receive, through the + terminal thereof, a voltage caused by the current I_{b} and the resistor R₃, and may receive, through the − terminal thereof, a voltage caused by the current Iₑ₁ and the resistor R₄.

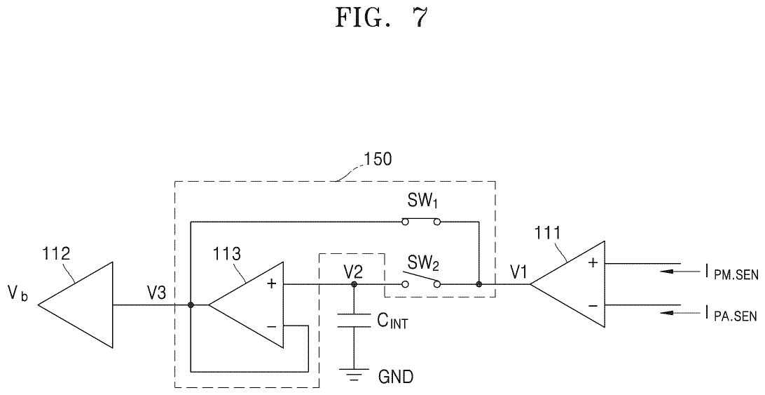

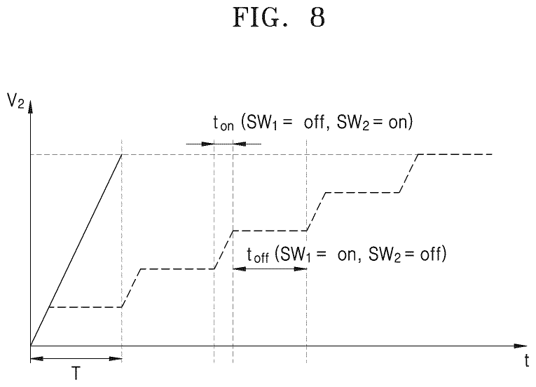

FIG. 7 is a diagram illustrating a capacitor amplification circuit according to embodiments. FIG. 8 is a diagram illustrating a capacitor amplification method according to embodiments.

Referring to FIGS. 6 and 7, the current balancing circuit 110 described above may include a capacitor amplification circuit 150.

The capacitor amplification circuit 150 may amplify the effective capacitance of the capacitor Cᵢₙₜ when charging the capacitor Cᵢₙₜ based on the voltage of a voltage node V1. The output node of the amplifier 111 is a node V1, the input node of the inverting circuit 112 is a node V3, and the capacitor Cᵢₙₜ may be connected to a node V2.

The capacitor amplification circuit 150 may include an amplifier 113 and switches SW₁ and SW₂. The amplifier 113 may be connected to the node V2 and the node V3. Specifically, the + terminal of the amplifier 113 may be connected to the node V2, and the − terminal of the amplifier 113 may be connected to the node V3. The switch SW₁ may connect the node V1 to the node V3. The switch SW₂ may connect the node V1 to the node V2. The switch SW₁ and the switch SW₂ may be switched complementarily. For example, when the switch SW₁ is turned on, the switch SW₂ may be turned off, and when the switch SW₁ is turned off, the switch SW₂ may be turned on.

Referring to FIG. 8, the voltage of the node V2 to which the capacitor Cᵢₙₜ is connected may represent a charge voltage of the capacitor Cᵢₙₜ. When charging the capacitor Cᵢₙₜ, a sample operation and a hold operation may be performed alternately. The sample operation and the hold operation may be performed every cycle T, and the sample operation may be performed in a period tₒₙ and the hold operation may be performed in a period toff.

During the sample operation, the switch SW₁ may be turned off and the switch SW₂ may be turned on. During the sample operation, because the node V1 and the node V2 are connected to each other, the charge voltage of the capacitor Cᵢₙₜ may increase. Furthermore, during the sample operation, the amplifier 113 may increase the voltage of the node V3 as the voltage of the node V2 increases. That is, the voltage of the node V2 may be transferred to the node V3.

During the hold operation, the switch SW₁ may be turned on and the switch SW₂ may be turned off. During the hold operation, because the node V1 and the node V2 are disconnected from each other, the charge voltage of the capacitor Cᵢₙₜ may be maintained constant.

Because the capacitor Cᵢₙₜ is charged only in the period tₒₙ during the cycle T, the effective capacitance of the capacitor Cᵢₙₜ may increase by T/tₒₙ times more than the capacitance of the capacitor Cᵢₙₜ.

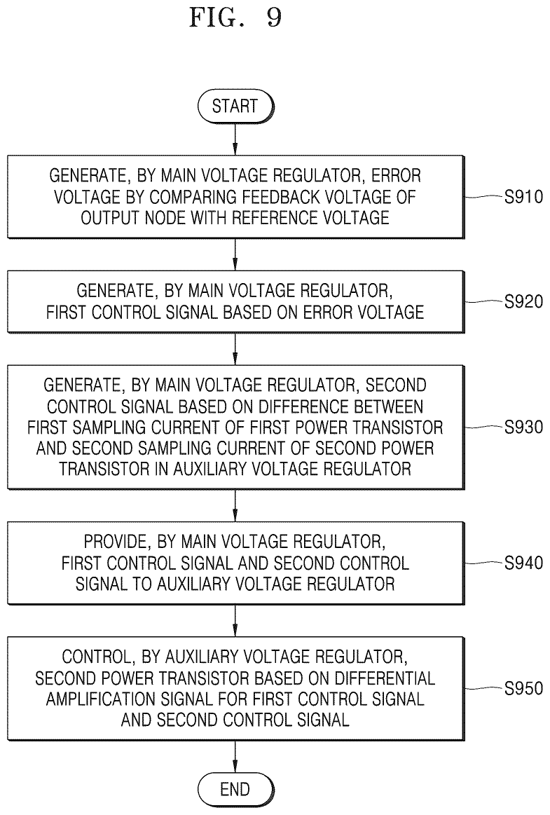

FIG. 9 is a flowchart illustrating an operating method of a distributed voltage regulating circuit according to embodiments. FIG. 9 may be described with reference to the drawings described above.

Referring to FIG. 9, the main voltage regulator 100 may generate an error voltage Vₑ by comparing, to a reference voltage V_{REF}, a feedback voltage V_{FB} of an output node from which an output voltage Vₒᵤₜ is provided (Operation S910).

The main voltage regulator 100 may generate a first control signal Ctrl1 based on the error voltage Vₑ (Operation S920). In some embodiments, the error voltage Vₑ may be used as the first control signal Ctrl1. In some embodiments, the main voltage regulator 100 may generate a current Iₑ based on the error voltage Vₑ, and the current Iₑ may be used as the first control signal Ctrl1.

The main voltage regulator 100 may generate a second control signal Ctrl2 based on a difference between a first sampling current I_{MP.SEN} of a first power transistor M_{PM} in the main voltage regulator 100 and a second sampling current I_{MA.SEN} of a second power transistor M_{PA} in the auxiliary voltage regulator 200 (Operation S930). Specifically, the current balancing circuit 110 may charge a capacitor Cᵢₙₜ based on the difference between the first sampling current I_{MP.SEN} and the second sampling current I_{MA.SEN} and generate a second control signal Ctrl2 based on a charge voltage of the capacitor Cᵢₙₜ. The current balancing circuit 110 may generate a bias voltage V_{b} by inverting the voltage of a node V2 to which the capacitor Cᵢₙₜ is connected. In some embodiments, the bias voltage V_{b} may be used as the second control signal Ctrl2. In some embodiments, the main voltage regulator 100 may generate a bias current I_{b} based on the bias voltage V_{b}, and the bias current Ip may be used as the second control signal Ctrl2.

In some embodiments, the current balancing circuit 110 may perform a sample operation in a period tₒₙ of a cycle T and perform a hold operation in a period toff of the cycle T. During the sample operation, the current balancing circuit 110 may increase the charge voltage of the capacitor Cᵢₙₜ. During the hold operation, the current balancing circuit 110 may maintain the charge voltage of the capacitor Cᵢₙₜ constant. Because the capacitor Cᵢₙₜ is charged only in the period tₒₙ during the cycle T, the effective capacitance of the capacitor Cᵢₙₜ may increase by T/tₒₙ times more than the capacitance of the capacitor Cᵢₙₜ.

The main voltage regulator 100 may provide the first control signal Ctrl1 and the second control signal Ctrl2 to the auxiliary voltage regulator 200 (Operation S940). Specifically, the main voltage regulator 100 may provide the first control signal Ctrl1 to the auxiliary voltage regulator 200 through a first control line CL1, and may provide the second control signal Ctrl2 to the auxiliary voltage regulator 200 through a second control line CL2. As described above with reference to FIG. 3, because the first control line CL1 and the second control line CL2 are arranged adjacent to each other at a relatively close distance, common noise may be induced in the first and second control signals Ctrl1 and Ctrl2 transferred through the first and second control lines CL1 and CL2.

The auxiliary voltage regulator 200 may control the second power transistor M_{PA} based on a differential amplification signal for the first control signal Ctrl1 and the second control signal Ctrl2 (Operation S950). The auxiliary voltage regulator 200 may generate the differential amplification signal for the first and second control signals Ctrl1 and Ctrl2 to remove the noise induced in the first and second control signals Ctrl1 and Ctrl2. Accordingly, an electronic device including a distributed voltage regulating circuit may provide power stability that is robust to noise occurring in a signal transfer path.

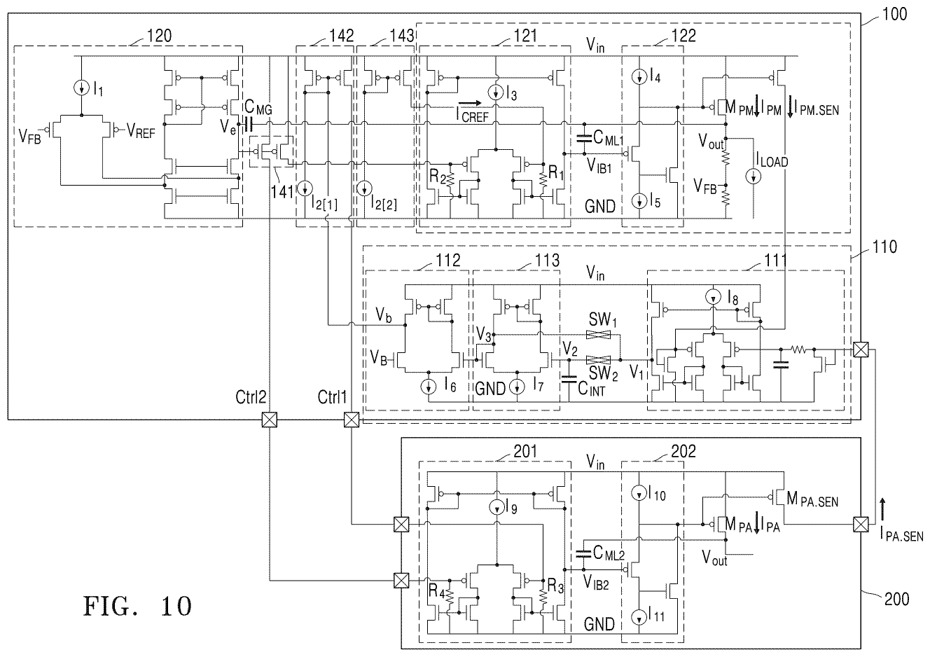

FIG. 10 is a circuit diagram of a distributed voltage regulating circuit according to embodiments.

Referring to FIG. 10, compared to the distributed voltage regulating circuit 5 of FIG. 6, the distributed voltage regulating circuit of FIG. 10 may include a current source 143. The current source 143 may generate a core reference current I_{CREF} based on a current source I_{2[2]}. The output node of the amplifier 121 may be referred to as V_{IB1}, and the output node of the amplifier 201 may be referred to as V_{IB2}. Furthermore, a voltage V_{B} may be applied to an input terminal of the inverting circuit 112.

The amplifier 120 operates based on a current source I₁, the amplifier 121 operates based on a current source I₃, the buffer 122 operates based on a current source I₄ and a current source I₅, the amplifier 111 operates based on a current source I₈, the amplifier 113 operates based on a current source I₇, the inverting circuit 112 operates based on a current source I₆, the amplifier 201 operates based on a current source I₉, and the buffer 202 operates based on a current source I₁₀ and a current source I₁₁. However, the structures of the amplifiers 120, 121, 112, 113, 111, and 201 are not limited thereto.

In some embodiments, the system-on-chip may further include a first control line configured to connect the main voltage regulator to the auxiliary voltage regulator and provide the first control signal, and a second control line configured to connect the main voltage regulator to the auxiliary voltage regulator and provide the second control signal, wherein the first control line and the second control line may be arranged on the same metal layer and extend substantially in parallel while being apart from each other by a preset distance or less.

In some embodiments, the main voltage regulator may further include a first amplifier configured to amplify an error between a feedback voltage sampled at the output node and a reference voltage, and a first conversion circuit configured to convert an output voltage of the first amplifier into a first control current used as the first control signal.

In some embodiments, the main voltage regulator may further include a second amplifier configured to generate a first differential amplification signal based on an output voltage of the first amplifier and a reference signal, and a first buffer configured to generate a first current control signal for controlling the first power transistor based on the first differential amplification signal, and the auxiliary voltage regulator may include a third amplifier configured to generate a second differential amplification signal based on the first control signal and the second control signal, and a second buffer configured to generate a second current control signal for controlling the second power transistor based on the second differential amplification signal.

In some embodiments, the main voltage regulator may further include a current balancing circuit including a fourth amplifier configured to generate a voltage provided to a capacitor by amplifying a difference between the first sampling current and the second sampling current, and a third buffer configured to generate a bias voltage based on a charge voltage of the capacitor, and the main voltage regulator may further include a second conversion circuit configured to convert the bias voltage into a second control current used as the second control signal.

In some embodiments, the current balancing circuit may connect an output node of the fourth amplifier to the capacitor in a first time period during a capacitance amplification operation and disconnect the output node of the fourth amplifier from the capacitor in a second time period.

While the disclosed concepts have been particularly shown and described with reference to embodiments thereof, it will be understood that various changes in form and details may be made therein without departing from the spirit and scope of the following claims.

What is claimed is:

1. A distributed voltage regulating circuit comprising:
a main voltage regulator comprising a first power transistor configured to provide a first current to an output node;
an auxiliary voltage regulator comprising a second power transistor configured to provide a second current to the output node; and
a first control line and a second control line connecting the main voltage regulator to the auxiliary voltage regulator,
wherein the main voltage regulator is configured to generate a first control signal and a second control signal, provide the first control signal to the auxiliary voltage regulator through the first control line, and provide the second control signal to the auxiliary voltage regulator through the second control line, and
the auxiliary voltage regulator is configured to generate a first differential amplification signal based on the first control signal and the second control signal and control the second power transistor based on the first differential amplification signal.

2. The distributed voltage regulating circuit of claim 1, wherein the first control line and the second control line are arranged on a same metal layer and extend substantially in parallel while being apart from each other by a preset distance or less.

3. The distributed voltage regulating circuit of claim 1, wherein the main voltage regulator comprises a first amplifier configured to amplify an error between a feedback voltage sampled at the output node and a reference voltage.

4. The distributed voltage regulating circuit of claim 3, wherein an output voltage of the first amplifier is provided to the auxiliary voltage regulator as the first control signal.

5. The distributed voltage regulating circuit of claim 3, wherein:
the main voltage regulator further comprises a first conversion circuit configured to convert an output voltage of the first amplifier into a first control current, and
the first control current is provided to the auxiliary voltage regulator as the first control signal.

6. The distributed voltage regulating circuit of claim 3, wherein:
the main voltage regulator further comprises a second amplifier configured to generate a second differential amplification signal based on an output voltage of the first amplifier and a reference signal,
the auxiliary voltage regulator comprises a third amplifier configured to generate the first differential amplification signal based on the first control signal and the second control signal, and
the first power transistor is configured to output the first current based on the second differential amplification signal, and the second power transistor is configured to output the second current based on the first differential amplification signal.

7. The distributed voltage regulating circuit of claim 6, wherein:
the main voltage regulator further comprises a second buffer configured to receive the second differential amplification signal and generate a first current control signal that controls the first power transistor, and
the auxiliary voltage regulator further comprises a third buffer configured to receive the first differential amplification signal and generate a second current control signal that controls the second power transistor.

8. The distributed voltage regulating circuit of claim 6, wherein the main voltage regulator further comprises:
a first capacitor connecting an output of the first amplifier to the output node; and
a second capacitor connecting an output of the second amplifier to the output node, and
the auxiliary voltage regulator further comprises a third capacitor connecting an output of the third amplifier to the output node.

9. The distributed voltage regulating circuit of claim 1, further comprising a feedback line configured to provide a sampling current of the second power transistor to the main voltage regulator,
wherein the main voltage regulator comprises a current balancing circuit configured to charge a capacitor based on a sampling current of the first power transistor and the sampling current of the second power transistor and generate a bias voltage based on a charge voltage of the capacitor.

10. The distributed voltage regulating circuit of claim 9, wherein the bias voltage is provided to the auxiliary voltage regulator as the second control signal.

11. The distributed voltage regulating circuit of claim 9, further comprising a second conversion circuit configured to convert the bias voltage into a second control current,
wherein the second control current is provided to the auxiliary voltage regulator as the second control signal.

12. The distributed voltage regulating circuit of claim 9, wherein the current balancing circuit comprises:
a fourth amplifier configured to amplify a difference between the sampling current of the first power transistor and the sampling current of the second power transistor to generate a voltage provided to the capacitor; and
an inverting circuit configured to generate the bias voltage based on the charge voltage of the capacitor.

13. The distributed voltage regulating circuit of claim 12, wherein the current balancing circuit further comprises:
a first switch connecting an output of the fourth amplifier to an input of the inverting circuit;
a second switch connecting the output of the fourth amplifier to the capacitor; and
a fifth amplifier configured to receive the charge voltage of the capacitor and a voltage of the input of the inverting circuit and provide an output voltage to the input of the inverting circuit.

14. The distributed voltage regulating circuit of claim 13, wherein the current balancing circuit is configured to:
perform a sample operation and a hold operation alternately,
turn on the first switch and turn off the second switch during the sample operation, and
turn off the first switch and turn on the second switch during the hold operation.

15. An operating method of a distributed voltage regulating circuit comprising a main voltage regulator and an auxiliary voltage regulator, the operating method comprising:
comparing, by the main voltage regulator, a feedback voltage of an output node with a reference voltage to generate an error voltage;
controlling, by the main voltage regulator, a first power transistor based on the error voltage to provide a first current to the output node;
generating, by the main voltage regulator, a first control signal based on the error voltage;
generating, by the main voltage regulator, a second control signal based on a current difference between a first sampling current of the first power transistor and a second sampling current of a second power transistor in the auxiliary voltage regulator;
providing, by the main voltage regulator, the first control signal and the second control signal to the auxiliary voltage regulator; and
controlling, by the auxiliary voltage regulator, the second power transistor based on a differential amplification signal for the first control signal and the second control signal to provide a second current to the output node.

16. The operating method of claim 15, wherein the providing, by the main voltage regulator, the first control signal and the second control signal to the auxiliary voltage regulator comprises:
providing the first control signal to the auxiliary voltage regulator through a first control line; and
providing the second control signal to the auxiliary voltage regulator through a second control line,
wherein the first control line and the second control line are arranged on a same metal layer and extend substantially in parallel while being apart from each other by a preset distance or less.

17. The operating method of claim 15, wherein the generating, by the main voltage regulator, a first control signal based on the error voltage comprises converting the error voltage into a first control current used as the first control signal.

18. The operating method of claim 15, wherein the generating, by the main voltage regulator, a second control signal based on a current difference between a first sampling current of the first power transistor and a second sampling current of a second power transistor in the auxiliary voltage regulator comprises:
generating a bias voltage based on the current difference; and
converting the bias voltage into a second control current used as the second control signal.

19. The operating method of claim 15, wherein the generating, by the main voltage regulator, a second control signal based on a current difference between a first sampling current of the first power transistor and a second sampling current of a second power transistor in the auxiliary voltage regulator comprises:
performing a sample operation connecting an amplifier, which amplifies the current difference between the first sampling current and the second sampling current, to a capacitor in a first time period; and
performing a hold operation disconnecting the amplifier from the capacitor in a second time period.

20. A system-on-chip comprising:
a main voltage regulator comprising a first power transistor configured to provide a first current to an output node based on a feedback voltage and a reference voltage;
an auxiliary voltage regulator comprising a second power transistor configured to provide a second current to the output node based on a first control signal and a second control signal; and
at least one load circuit configured to operate based on a voltage of the output node,
wherein the main voltage regulator is configured to generate the first control signal based on the feedback voltage and the reference voltage and generate the second control signal based on a first sampling current of the first power transistor and a second sampling current of the second power transistor.
